(19) United States
(12) Patent Application Publication
(10) Pub. No.: US 2026/0344439 A1
(43) Pub. Date: Oct. 29, 2026

(54) PACKAGE MODULE AND MANUFACTURING METHOD THEREOF

(71) Applicant: SILICONWARE PRECISION INDUSTRIES CO., LTD., Taichung City (TW)

(72) Inventors: Tzu-Yin MA, Taichung City (TW); Rung-Jeng LIN, Taichung City (TW); Meng-Han TSAI, Taichung City (TW); Chun-Sheng YEH, Taichung City (TW)

(73) Assignee: SILICONWARE PRECISION INDUSTRIES CO., LTD., Taichung City (TW)

(21) Appl. No.: 19/395,898

(22) Filed: Nov. 20, 2025

(30) Foreign Application Priority Data
Apr. 25, 2025 (TW) 114115746

(51) Int. Cl. H10W 42/00; H10W 70/60; H10W 74/01; H10W 90/00

(52) U.S. Cl. CPC H10W 42/121; H10W 74/01; H10W 90/701; H10W 70/611; H10W 90/00; H10W 90/401

(57) ABSTRACT

A package module and a method of manufacturing the package module are provided. A plurality of package units are formed on a carrier. Each of the plurality of package units includes a circuit structure, a plurality of electronic components disposed on the circuit structure, and a packaging layer encapsulating the plurality of electronic components. Then, an anti-warping layer is formed on the plurality of package units and covers the packaging layer to reduce problems caused by warpage.

### BACKGROUND

### 1. Technical Field

The present disclosure relates to a semiconductor packaging technology, and more particularly, to a package module including a plurality of package units and a method for manufacturing the same.

### 2. Description of Related Art

High performance computing (HPC) technology is increasingly important and widely applied in modern life, for example, in fields such as medical technology development (e.g., cancer drug development) or the automatic sensing and detection computation in autonomous vehicles. In these application areas, the package structures used in the equipment include, for example, the fan-out multi-chip module (FOMCM) structure and the fan-out embedded bridge (FOEB) die structure. These structures are characterized by features such as multiple chips, a high number of circuit layers, a large fan-out size, and high heat dissipation design.

Please refer to FIG. 1A to FIG. 1C for schematic cross-sectional views of a conventional fan-out package structure manufacturing method. First, a plurality of conductive pillars 11 are formed on a carrier 10 and a plurality of semiconductor chips 12 are disposed on the carrier 10. Next, an encapsulation layer 13 is formed on the carrier 10, so that the encapsulation layer 13 encapsulates the semiconductor chips 12 and the plurality of conductive pillars 11. Then, a circuit structure 14 is formed on the encapsulation layer 13. After that, a plurality of electronic components 15 are disposed on the circuit structure 14, and a packaging layer 16 is formed to encapsulate the plurality of electronic components 15. Finally, the carrier 10 is removed and a plurality of solder balls 17 are bonded.

However, in the above-described process, after the formation of the packaging layer 16, the carrier 10 must be removed to carry out the placement operation of the solder balls 17. Due to stress issues, once the carrier 10 is removed the entire structure warps, resembling a smiling or frowning shape, resulting in difficulties or inability to operate in subsequent process stations (e.g., during solder ball placement when the warpage prevents the suction head of a robotic arm from achieving proper vacuum suction).

Therefore, how to overcome the aforementioned problems of the prior art has become an urgent issue to be solved.

### SUMMARY

In view of the aforementioned shortcomings of the prior art, the present disclosure provides a package module implemented as a monolithic structure, and the package module comprises: a plurality of package units, each of the plurality of package units including a circuit structure, a plurality of electronic components disposed on the circuit structure, and a packaging layer encapsulating the plurality of electronic components; and an anti-warping layer formed on the plurality of package units and covering the packaging layer.

The present disclosure also provides a method of manufacturing a package module, and the method comprises: forming a plurality of package units on a carrier, wherein each of the plurality of package units includes a circuit structure, a plurality of electronic components disposed on the circuit structure, and a packaging layer encapsulating the plurality of electronic components; and forming an anti-warping layer on the plurality of package units to cover the packaging layer.

In the aforementioned package module and method, each of the plurality of package units further includes bridge dies disposed on and electrically connected to the circuit structure.

In the aforementioned package module and method, each of the plurality of package units further includes a plurality of conductive pillars disposed on and electrically connected to the circuit structure.

In the aforementioned package module and method, each of the plurality of package units further includes an encapsulation layer formed on the circuit structure and encapsulating the bridge dies and the plurality of conductive pillars.

The aforementioned method further comprises: removing the carrier; forming a circuit portion on the encapsulation layer, the circuit portion being electrically connected to the plurality of conductive pillars; and disposing a plurality of conductive components on the circuit portion, the plurality of conductive components being electrically connected to the circuit portion.

The aforementioned method further comprises: removing the carrier; and disposing a plurality of conductive components on the circuit structure, the plurality of conductive components being electrically connected to the circuit structure.

The aforementioned method further comprises: removing the anti-warping layer and a portion of the packaging layer to expose the plurality of electronic components.

In the aforementioned package module and method, each of the plurality of package units is a fan-out embedded bridge die structure or a fan-out multi-chip module structure.

In the aforementioned package module and method, a thickness of each of the plurality of package units is 900 micrometers to 1400 micrometers. An aspect ratio of each of the plurality of electronic components is between 1.5 and 3. A thickness of the anti-warping layer is 50 micrometers to 100 micrometers.

As can be understood from the above, in the package module and the method of manufacturing the package module according to the present disclosure, an anti-warping layer is formed on the packaging layer of a plurality of package units in a monolithic structure. By employing an adhesive film with reverse stress expansion characteristics, the significant warpage caused by the conventional manufacturing process is improved, thereby ensuring operability at subsequent process stations and reducing problems due to warpage.

### BRIEF DESCRIPTION OF THE DRAWINGS

FIG. 1A to FIG. 1C are schematic cross-sectional views illustrating a conventional method of manufacturing a fan-out package structure.

FIG. 2A to FIG. 2E are schematic cross-sectional views illustrating a method of manufacturing a package module according to a first embodiment of the present disclosure.

FIG. 3A to FIG. 3C are schematic cross-sectional views illustrating a method of manufacturing a package module according to a second embodiment of the present disclosure.

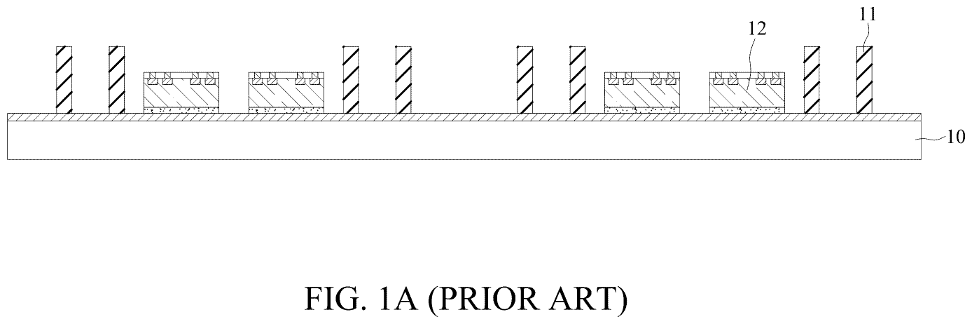

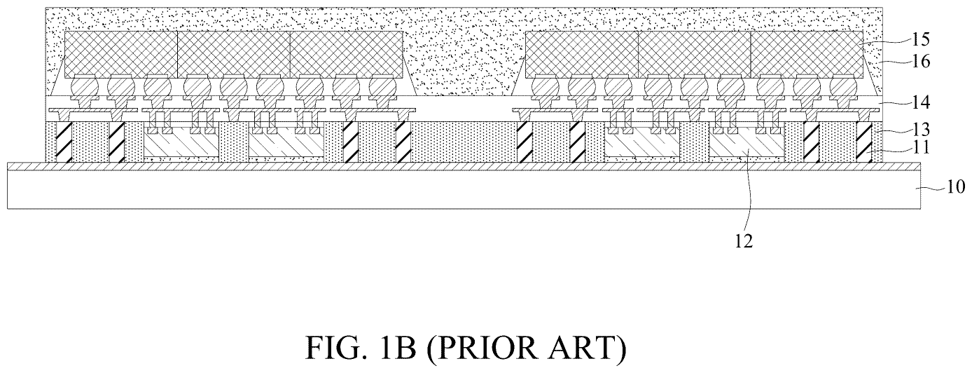

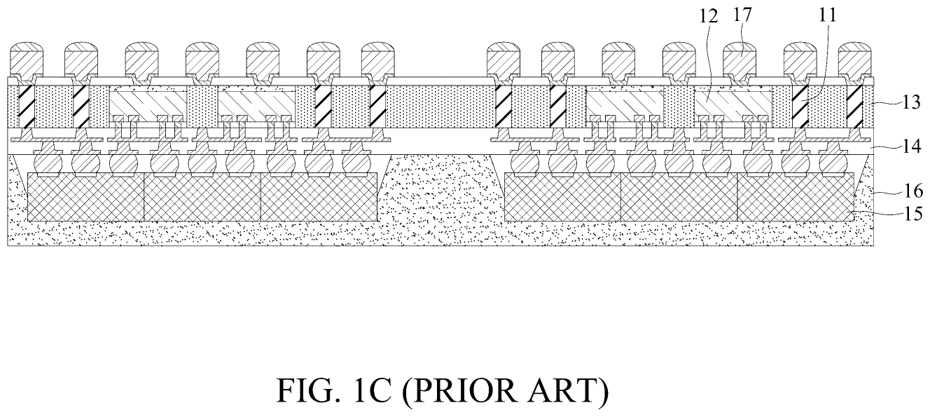

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

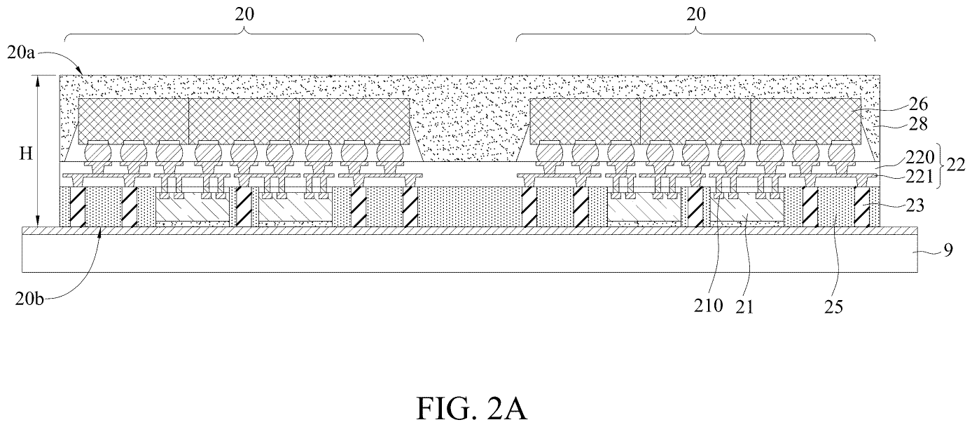

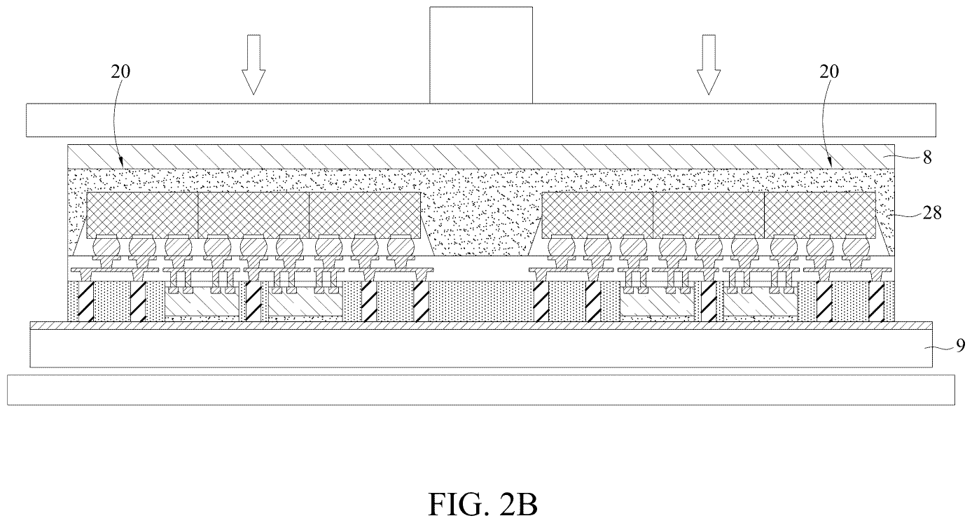

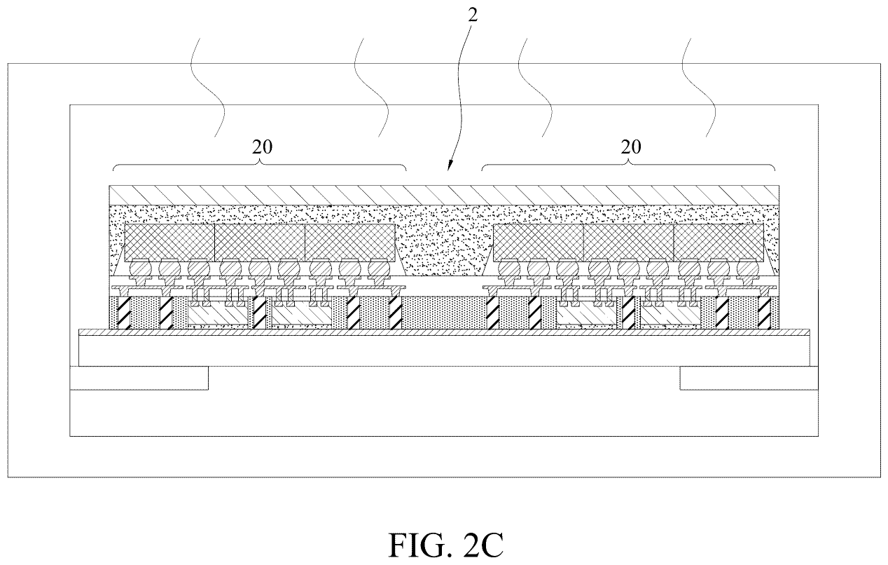

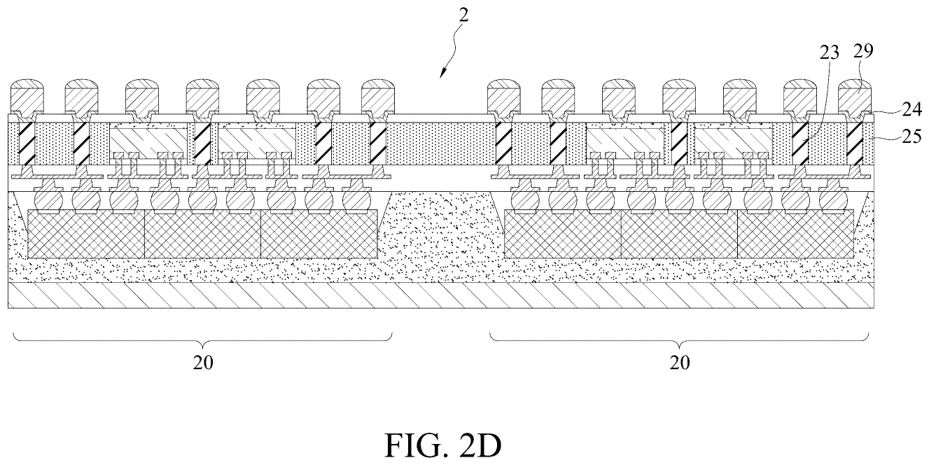

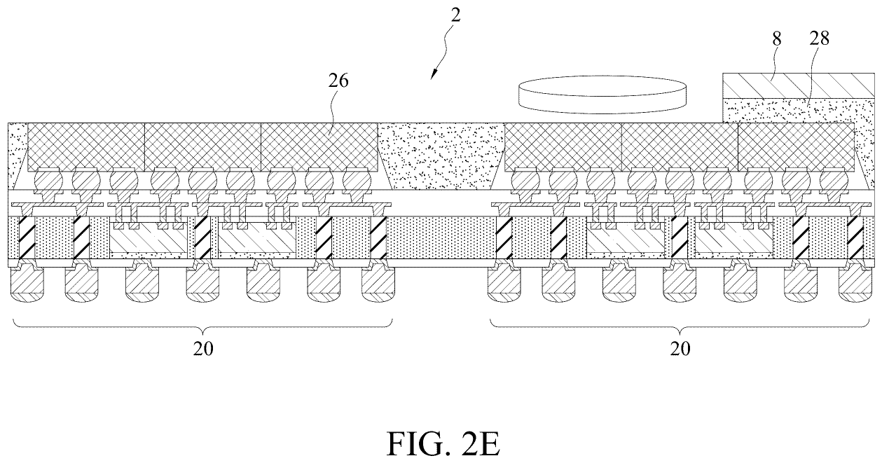

FIG. 2A to FIG. 2E are schematic cross-sectional views illustrating a method of manufacturing a package module 2 according to a first embodiment of the present disclosure. The package module 2 of the present disclosure is implemented as a monolithic structure (in wafer form or panel form) and includes a plurality of packaging regions.

As shown in FIG. 2A, a carrier 9 (e.g., a carrier board) is provided, and a plurality of conductive pillars 23 are formed on the carrier 9 and a plurality of bridge dies 21 (e.g., bridge chips) are disposed on the carrier 9. The plurality of conductive pillars 23 surround the bridge dies 21, wherein each of the bridge dies 21 is bonded with and electrically connected to a plurality of conductors 210. The plurality of conductors 210 are spherical in shape (as in solder balls), columnar (as in copper pillars or solder bumps made of a metal material), or stud-shaped conductive members made by a wire bonding machine, among other forms. Moreover, each of the bridge dies 21 has an active surface and an inactive surface opposite to the active surface. The bridge dies 21 are bonded to the carrier 9 by their inactive surfaces. The active surface of each of the bridge dies 21 has a plurality of electrode pads and a protective film made of such as a passivation material, and the conductors 210 are disposed on the electrode pads and embedded in the protective film.

Then, an encapsulation layer 25 is formed on the carrier 9, so that the encapsulation layer 25 encapsulates the bridge dies 21, the plurality of conductors 210, and the plurality of conductive pillars 23. In one embodiment, the encapsulation layer 25 is made of an insulating material such as polyimide (PI), dry film, epoxy molding colloid, or epoxy molding compound. In addition, by means of a planarization process, the end surfaces of the plurality of conductive pillars 23 and the end surfaces of the plurality of conductors 210 are exposed from the encapsulation layer 25.

Afterwards, a circuit structure 22 is formed on the encapsulation layer 25 and is electrically connected to the plurality of conductive pillars 23 and the plurality of conductors 210. The circuit structure 22 comprises a plurality of dielectric layers 220 and a plurality of redistribution layers (RDLs) 221 formed on the dielectric layers 220. Alternatively, the circuit structure 22 may also comprise only a single dielectric layer 220 and a single redistribution layer 221. Furthermore, the redistribution layer 221 is made of copper, and the dielectric layer 220 is made of a dielectric material such as polybenzoxazole (PBO), polyimide (PI), or prepreg (PP), among others.

Next, a plurality of electronic components 26 are disposed on the circuit structure 22, and a packaging layer 28 is formed (for example, by a molding process) to encapsulate the plurality of electronic components 26. Each of the electronic components 26 may be an active component, a passive component, or a combination of the active component and the passive component. In one embodiment, the electronic components 26 are, for example, semiconductor chips such as graphics processing units (GPUs), high bandwidth memory (HBM), etc. The electronic components 26 are electrically connected to the circuit structure 22 via a plurality of conductive bumps such as solder bumps, copper bumps, or others. Moreover, at least two of the electronic components 26 may be electrically connected to each other via the bridge die 21. Furthermore, the packaging layer 28 is made of an insulating material such as polyimide (PI), dry film, epoxy molding colloid, or epoxy molding compound, and the packaging layer 28 can be formed on the circuit structure 22 by lamination or molding. It should be understood that the material forming the packaging layer 28 and the material forming the encapsulation layer 25 can be the same or different. Additionally, an underfill may be formed between the electronic components 26 and the circuit structure 22 to encapsulate the plurality of conductive bumps, and the packaging layer 28 is then formed to encapsulate the underfill and the plurality of electronic components 26. The formation of the underfill between the electronic components 26 and the circuit structure 22 is optional.

Accordingly, after the packaging layer 28 is formed by the molding process, a plurality of package units 20 are formed on the carrier 9, wherein each of the package units 20 has a first side 20a and a second side 20b opposite to the first side 20a, and each of the package units 20 includes the circuit structure 22, the plurality of electronic components 26 disposed on the circuit structure 22, and the packaging layer 28 encapsulating the electronic components 26. The thickness H of each of the package units 20 is about 900 micrometers to 1400 micrometers, and the aspect ratio (length-to-width) of each of the electronic components 26 is between 1.5 and 3.

As shown in FIG. 2B and FIG. 2C, an anti-warping layer 8 is formed on the plurality of package units 20 to obtain the package module 2 of the present disclosure. In one embodiment, an adhesive film is formed on the packaging layer 28 of the plurality of package units 20 by lamination. Then, the plurality of package units 20 having the adhesive film are transferred into an oven for a curing process so that the anti-warping layer 8 is formed on the plurality of package units 20. The thickness of the anti-warping layer 8 is about 50 μm to 100 μm.

As shown in FIG. 2D, subsequently, the carrier 9 can be removed, and a plurality of conductive components 29 are formed on the second side of the plurality of package units 20. With the anti-warping layer 8 in place, the reverse-stress adhesive film expands to ameliorate the substantial warpage that might result from the molding process used to form the packaging layer. This permits operability during subsequent processing stages (such as during the placement of the plurality of conductive components), thereby reducing problems caused by warpage.

In one embodiment, a circuit portion 24 may be formed on the encapsulation layer 25 to electrically connect the plurality of conductive pillars 23. The circuit portion 24 may further include an insulating layer and an under-bump metallization (UBM) layer to bond the plurality of conductive components 29 such as solder bumps or solder balls (such as those of Controlled Collapse Chip Connection type or C4 type). Alternatively, the circuit portion 24 may be formed on the encapsulation layer 25 via an RDL process for bonding the conductive components 29.

As shown in FIG. 2E, a thinning process may also be performed, for example, via a grinding operation, to remove the anti-warping layer 8 and a portion of the packaging layer 28. This exposes the plurality of electronic components 26 to provide improved heat dissipation.

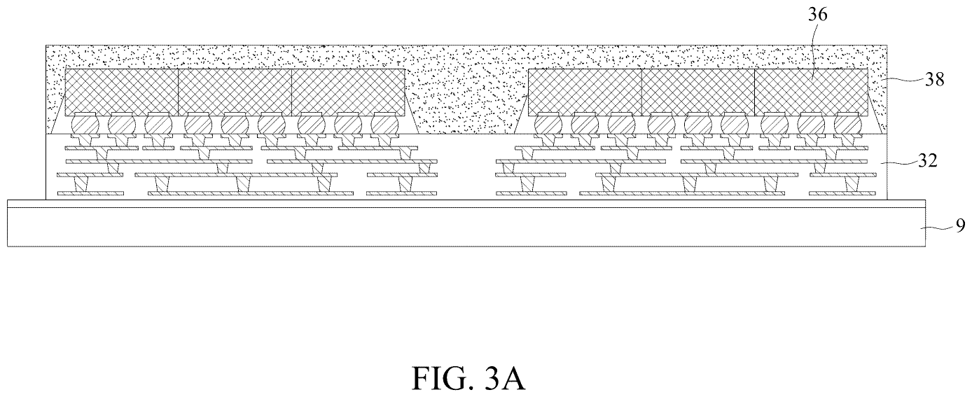

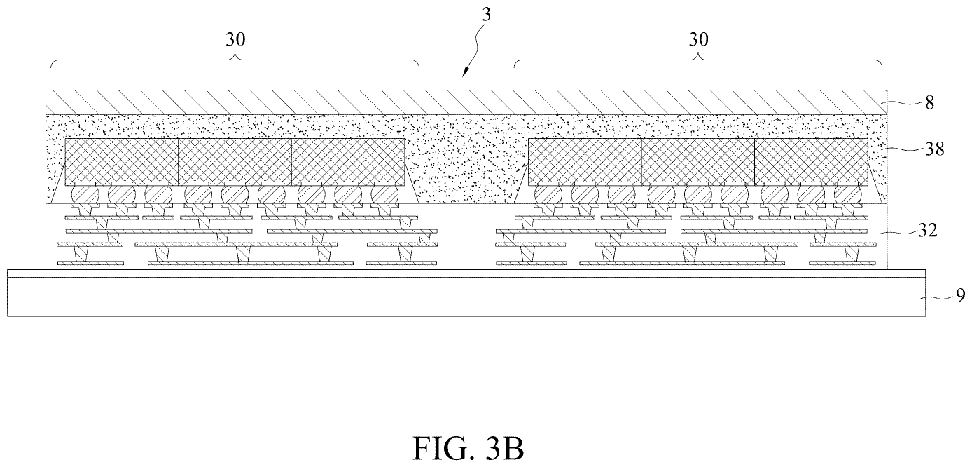

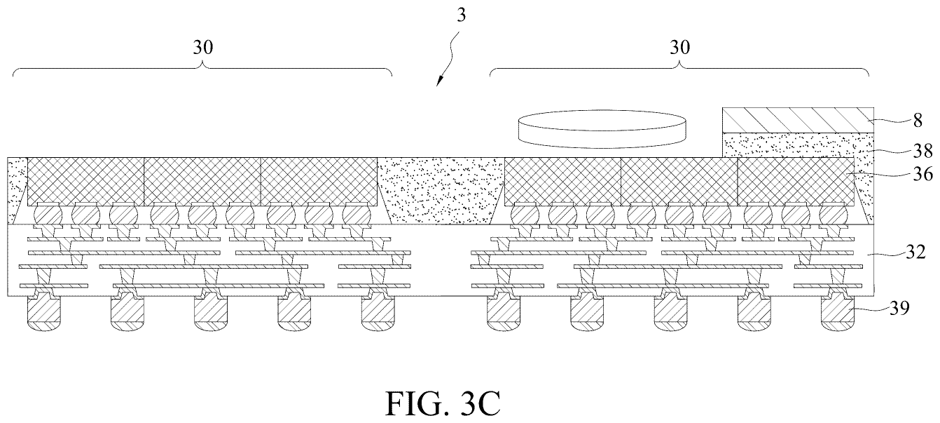

Please refer to FIG. 3A to FIG. 3C, which are schematic cross-sectional views illustrating a method of manufacturing a package module 3 according to a second embodiment of the present disclosure. The package module 3 of the present disclosure is implemented as a monolithic structure (in wafer form or panel form) and includes a plurality of packaging regions.

As shown in FIG. 3A, a carrier 9 (e.g., a carrier board) is provided, and a circuit structure 32 is formed on the carrier 9. Then, a plurality of electronic components 36 are disposed on the circuit structure 32, and a packaging layer 38 is formed on the circuit structure 32 to encapsulate the plurality of electronic components 36, thereby forming a plurality of package units 30. The circuit structure 32 comprises a plurality of dielectric layers and a plurality of redistribution layers. Each of the electronic components 36 is an active component, a passive component, or a combination of the active component and the passive component.

As shown in FIG. 3B, an anti-warping layer 8 is formed on the plurality of package units 30 to obtain the package module 3 of the present disclosure. In one embodiment, an adhesive film is formed on the packaging layer 38 of the plurality of package units 30 by lamination. Then, the plurality of package units 30 having the adhesive film are transferred into an oven for a curing process, thereby forming the anti-warping layer 8 on the plurality of package units 30 and thus obtaining the package module 3 of the present disclosure.

As shown in FIG. 3C, subsequently the carrier 9 may be removed, and a plurality of conductive components 39 are disposed on the other side of the circuit structure 32 (i.e., the side opposite to that having the electronic components 36). A thinning process is then performed, such as via grinding, to remove the anti-warping layer 8 and a portion of the packaging layer 38, thereby exposing the plurality of electronic components 36 to provide improved heat dissipation.

By means of the aforementioned method, the present disclosure provides a package module 2, 3 implemented as a monolithic structure, and the package module 2, 3 comprises: a plurality of package units 20, 30, wherein each of the plurality of package units 20, 30 includes a circuit structure 22, 32, a plurality of electronic components 26, 36 disposed on the circuit structure 22, 32, and a packaging layer 28, 38 encapsulating the plurality of electronic components 26, 36; and an anti-warping layer 8 formed on the plurality of package units 20, 30 and covering the packaging layer 28, 38.

In one embodiment, each of the plurality of package units 20 is, for example, a fan-out embedded bridge (FOEB) die structure that further includes a plurality of conductive pillars 23 and bridge dies 21 disposed on the circuit structure 22, an encapsulation layer 25 formed on the circuit structure 22 and encapsulating the plurality of conductive pillars 23 and the bridge dies 21, a circuit portion 24 disposed on the encapsulation layer 25, and a plurality of conductive components 29 disposed on the circuit portion 24. The bridge dies 21 and the plurality of conductive pillars 23 are electrically connected to the circuit structure 22. The plurality of conductive pillars 23 are embedded in the encapsulation layer 25 and surround the bridge dies 21. The circuit portion 24 is electrically connected to the plurality of conductive pillars 23 and the plurality of conductive components 29.

In one embodiment, each of the plurality of package units 30 is, for example, a fan-out multi-chip module (FOMCM) structure that further includes a plurality of conductive components 39 disposed on the circuit structure 32, wherein the plurality of conductive components 39 are electrically connected to the circuit structure 32.

To sum up, in the package module and the method of manufacturing the package module according to the present disclosure, an anti-warping layer is formed on the packaging layer of a plurality of package units in a monolithic structure. By employing an adhesive film with reverse stress expansion characteristics, the significant warpage caused by the conventional manufacturing process is improved, thereby ensuring operability at subsequent process stations and reducing problems due to warpage. In addition, the aforementioned structure does not require the development of new processes or materials nor the purchase of additional equipment. Existing materials, processes, and equipment are sufficient to resolve the current technical issues in the industry, thereby avoiding significant additional costs.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package module implemented as a monolithic structure, and the package module comprising:
a plurality of package units, each of the plurality of package units including a circuit structure, a plurality of electronic components disposed on the circuit structure, and a packaging layer encapsulating the plurality of electronic components; and
an anti-warping layer formed on the plurality of package units and covering the packaging layer.

2. The package module of claim 1, wherein each of the plurality of package units further includes bridge dies disposed on and electrically connected to the circuit structure.

3. The package module of claim 2, wherein each of the plurality of package units further includes a plurality of conductive pillars disposed on and electrically connected to the circuit structure.

4. The package module of claim 3, wherein each of the plurality of package units further includes an encapsulation layer formed on the circuit structure and encapsulating the bridge dies and the plurality of conductive pillars.

5. The package module of claim 4, wherein each of the plurality of package units further includes a circuit portion disposed on the encapsulation layer and electrically connected to the plurality of conductive pillars.

6. The package module of claim 5, wherein each of the plurality of package units further includes a plurality of conductive components disposed on and electrically connected to the circuit portion.

7. The package module of claim 1, wherein each of the plurality of package units further includes a plurality of conductive components disposed on and electrically connected to the circuit structure.

8. The package module of claim 1, wherein each of the plurality of package units is a fan-out embedded bridge die structure or a fan-out multi-chip module structure.

9. The package module of claim 1, wherein a thickness of each of the plurality of package units is 900 micrometers to 1400 micrometers.

10. The package module of claim 1, wherein an aspect ratio of each of the plurality of electronic components is between 1.5 and 3.

11. The package module of claim 1, wherein a thickness of the anti-warping layer is 50 micrometers to 100 micrometers.

12. A method of manufacturing a package module, comprising:
forming a plurality of package units on a carrier, wherein each of the plurality of package units includes a circuit structure, a plurality of electronic components disposed on the circuit structure, and a packaging layer encapsulating the plurality of electronic components; and
forming an anti-warping layer on the plurality of package units to cover the packaging layer.

13. The method of claim 12, wherein each of the plurality of package units further includes bridge dies disposed on and electrically connected to the circuit structure.

14. The method of claim 13, wherein each of the plurality of package units further includes a plurality of conductive pillars disposed on and electrically connected to the circuit structure.

15. The method of claim 14, wherein each of the plurality of package units further includes an encapsulation layer formed on the circuit structure to encapsulate the bridge dies and the plurality of conductive pillars.

16. The method of claim 15, further comprising:
removing the carrier;
forming a circuit portion on the encapsulation layer, the circuit portion being electrically connected to the plurality of conductive pillars; and
disposing a plurality of conductive components on the circuit portion, the plurality of conductive components being electrically connected to the circuit portion.

17. The method of claim 12, further comprising:
removing the carrier; and
disposing a plurality of conductive components on the circuit structure, the plurality of conductive components being electrically connected to the circuit structure.

18. The method of claim 12, further comprising: removing the anti-warping layer and a portion of the packaging layer to expose the plurality of electronic components.

19. The method of claim 12, wherein each of the plurality of package units is a fan-out embedded bridge die structure or a fan-out multi-chip module structure.

20. The method of claim 12, wherein a thickness of each of the plurality of package units is 900 micrometers to 1400 micrometers.

21. The method of claim 12, wherein an aspect ratio of each of the plurality of electronic components is between 1.5 and 3.

22. The method of claim 12, wherein a thickness of the anti-warping layer is 50 micrometers to 100 micrometers.
